(19) United States
(12) Patent Application Publication
(10) Pub. No.: US 2014/0184256 A1
(43) Pub. Date: Jul. 3, 2014

(54) POSITIONING DEVICE AND POSITIONING METHOD

(71) Applicant: HON HAI PRECISION INDUSTRY CO., LTD., New Taipei (TW)

(72) Inventor: TEN-CHEN HO, New Taipei (TW)

(73) Assignee: HON HAI PRECISION INDUSTRY CO., LTD., New Taipei (TW)

(21) Appl. No.: 13/895,370

(22) Filed: May 16, 2013

(30) Foreign Application Priority Data
Dec. 27, 2012 (CN) 2012105783259

(51) Int. Cl. G01R 31/28

(52) U.S. Cl. CPC G01R 31/2887
USPC 324/750.16

(57) ABSTRACT

An exemplary positioning method controls a capturing unit to capture an image of a product. The method then determines a label in the captured image. Next, the method determines a virtual distance along a X-axis and a virtual distance along the Y-axis between the capturing unit and the label in the image to determine an actual distance along the X-axis and an actual distance along the Y-axis between the discharging unit and the label according to a stored ratio and a detected distance between the capturing unit and the discharging unit along the Y-axis. The method then controls the driving device to drive the discharging unit to move the determined actual distance along the X-axis in the X direction, the determined actual distance along the Y-axis in the Y direction, and a stored distance between the label and the discharging unit along the Z-axis in the Z direction.

### BACKGROUND

1. Technical Field

The present disclosure relates to positioning devices and positioning methods and, particularly, to a positioning device capable of automatically positioning a target test spot of an object and a positioning method thereof.

2. Description of Related Art

A discharging unit is employed to perform an electrostatic discharge (ESD) test of each test spot of an object, to test the static electricity that the object can stand. However, the discharging unit is usually manually positioned to aim at the test spot. This manual action may cause the discharging unit to be departed from the test spot, thus the precision of the ESD test may decrease.

### BRIEF DESCRIPTION OF THE DRAWINGS

The components of the drawings are not necessarily drawn to scale, the emphasis instead being placed upon clearly illustrating the principles of the present disclosure. Moreover, in the drawings, like reference numerals designate corresponding parts throughout several views.

FIG. 1 is a schematic view of a positioning device in accordance with an exemplary embodiment.

FIG. 2 is a block diagram of the positioning device of FIG. 1.

FIG. 3 is a block diagram of a processor of the positioning device of FIG. 1.

FIG. 4 is a flowchart of a positioning method in accordance with an exemplary embodiment.

### DETAILED DESCRIPTION

The embodiments of the present disclosure are described with reference to the drawings.

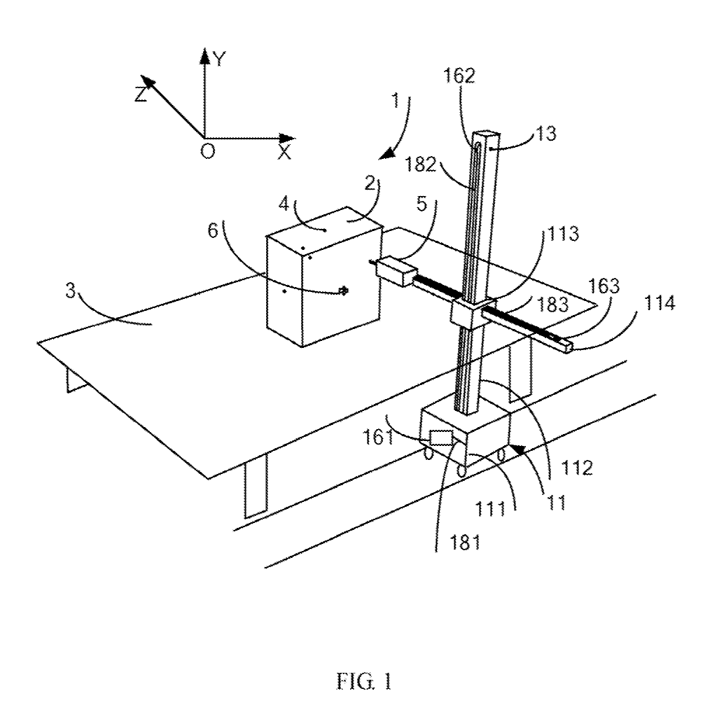

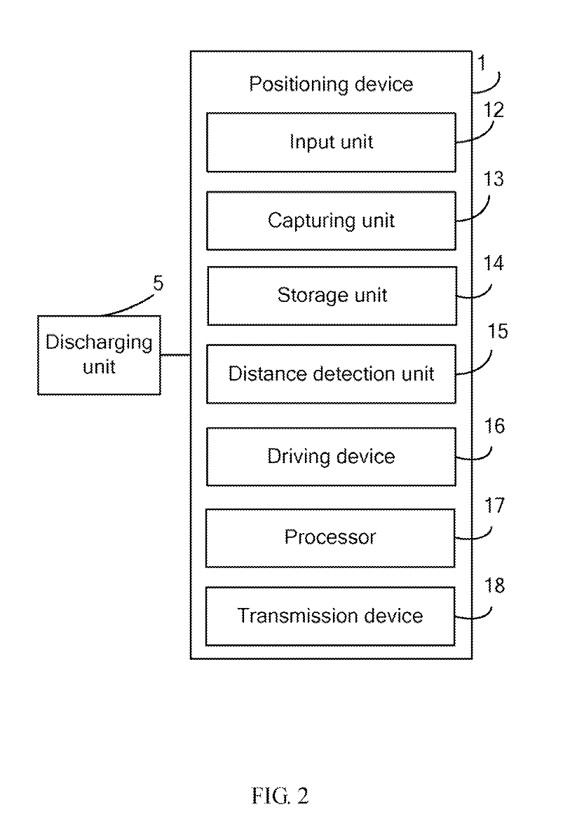

FIGS. 1-2 show a positioning device 1 in accordance with an exemplary embodiment. The positioning device 1 can capture an image of a product 2 placed on a platform 3, determine the position of a target test spot 4 of the product 2 according to the obtained image, and perform an ESD test on the positioned target test spot 4 via a discharging unit 5. In the embodiment, each product 2 includes a number of test spots 4. Before performing the ESD test, a label 6 is manually attached to one test spot 4 to identify the target test spot 4, and the positioning device 1 determines the position of the target test spot 4 by determining the position of the label 6. In this embodiment, during test, the product 2 can be manually turned over to cause each test spot 4 to be tested.

In this embodiment, the positioning device 1 includes a supporting member 11, an input unit 12, a capturing unit 13, a storage unit 14, a distance detection unit 15, a driving device 16, and a processor 17. The discharging unit 5 is movably arranged on the supporting member 11 and can be moved to aim at the target test spot 4. The capturing unit 13 is fixed to the supporting member 11 and configured to capture an image of the product 2. In the embodiment, the product 2 is placed on a fixed position of the platform 3, thus in a X-Y-Z coordinate system, a distance between the label 6 and the discharging unit 5 along the Z-axis is a fixed value, and the distance between the capturing unit 13 and the label 6 along the Z-axis is a fixed value, accordingly a ratio of the image size of the object in the captured image to real-life size of the object (hereinafter, ratio) is a fixed value. The storage unit 14 stores the ratio and the distance between the label 6 and the discharging unit 5 along the Z-axis. The distance detection unit 15 is configured to detect a distance between the capturing unit 13 and the discharging unit 5 along the Y-axis. The driving device 16 is configured to drive the discharging unit 5 to move in an X-Y-Z coordinate system. The processor 17 is configured to control the capturing unit 13 to capture an image of the product 2 in response to a user operation on the input unit 12, and determine the label 6 in the captured image. The processor 17 is further to determine an actual distance along the X-axis and an actual distance along the Y-axis between the discharging unit 5 and the label 6, and control the driving device 16 to drive the discharging unit 5 to move the determined actual distance along the X-axis in the X direction, the determined actual distance along the Y-axis in the Y direction, and the stored distance between the label 6 and the discharging unit 5 in the Z direction. The detail method of how to determine the above-mentioned distances will be described below. In the embodiment, the processor 17 is further configured to control the discharging unit 5 to discharge a preset number.

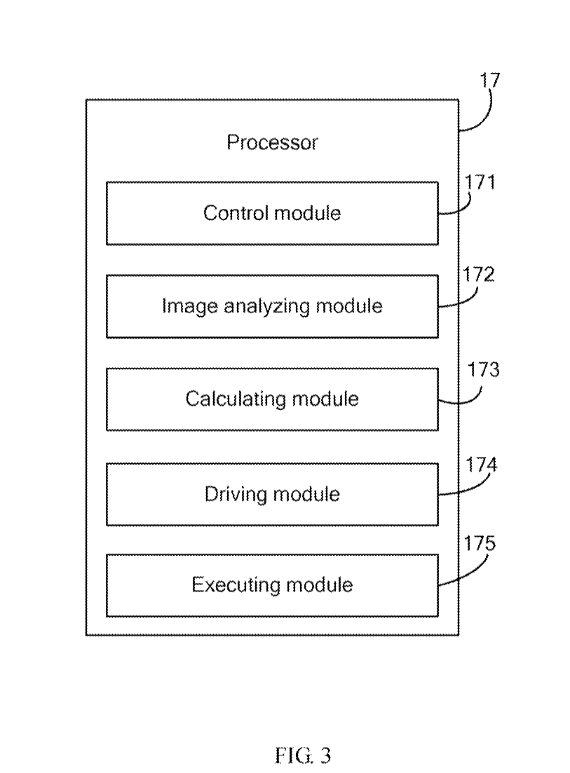

FIG. 3 shows that the processor 17 includes a control module 171, an image analyzing module 172, a calculating module 173, and a driving module 174.

The control module 171 is configured to control the capturing unit 13 to capture an image of the product 2 in response to the user operation on the input unit 12.

The image analyzing module 172 is configured to determine the label 6 in the captured image. In the embodiment, the color of the label 6 is a special color which is different from the color of the product 2 and the platform 3. The image analyzing module 172 identifies the special color in the image to determine the label 6. In other embodiments, the storage unit 14 further stores the shape template of the label 6 which is different from the shape of the product 2 and the platform 3. The image analyzing module 172 determines that an object in the image whose shape is the same as the stored shape template is the label 6.

The calculating module 173 is configured to determine the actual distance along the X-axis and the actual distance along the Y-axis between the discharging unit 5 and the label 6.

In detail, a center point of the captured image is considered as a center of the projected area of the capturing unit 13 in the image. A two-dimensional Cartesian coordinate system is established and the center of the captured image is set to be the origin or zero point of the Cartesian coordinate system. The calculating module 173 determines a set of coordinate of the label 6 in the image, determines a virtual distance along the X-axis and a virtual distance along the Y-axis between the center point of the captured image and the label 6 in the captured image, and determines an actual distance along the X-axis and an actual distance along the Y-axis between the capturing unit 13 and the label 6 in the real-life according to the stored ratio, the determined virtual distance along the X-axis, and the determined virtual distance along the Y-axis. The calculating module 173 further determines the determined actual distance along the X-axis between the capturing unit 13 and the label 6 is the actual distance along the X-axis between the discharging unit 5 and the label 6, obtains the distance between the capturing unit 13 and the discharging unit 5 along the Y-axis detected by the distance detection unit 15, and determines that the actual distance along the Y-axis between the capturing unit 13 and the label 6 subtracting the distance between the capturing unit 13 and the discharging unit 5 along the Y-axis is the actual distance along the Y-axis between the discharging unit 5 and the label 6.

The driving module 174 is configured to control the driving device 16 to drive the discharging unit 5 to move in the X direction the determined actual distance along the X-axis between the discharging unit 5 and the label 6, move in the Y direction the determined actual distance along the Y-axis between the discharging unit 5 and the label 6, and move in the Z direction the stored distance between the label 6 and the discharging unit 5 along the Z-axis. Thus the discharging unit 5 can be moved to aim at the label 6, and accordingly aim at the target test spot 4.

In the embodiment, the processor 17 further includes an executing module 175 configured to control the discharging unit 5 to discharge a preset number.

FIG. 1 further shows that the supporting member 11 includes a base 111 and a supporting arm 112. The base 11 can be moved along a side of the platform 3. The supporting arm 112 is perpendicularly secured to the base 111. The capturing unit 13 is fixed to the supporting arm 112. The supporting member 11 further includes a sliding block 113 and an extending arm 114. The sliding block 113 is slidably sleeved on the supporting arm 112. The extending arm 114 perpendicularly extends through the sliding block 113 and the supporting arm 112 and is fixed to the sliding block 113. The discharging unit 5 is arranged on an end of the extending arm 114 and can be moved in the Z direction. With such configuration, when the sliding block 113 is moved along the supporting arm 112, the discharging unit 5 is accordingly moved in the Y direction, and when the base 111 is moved along the side of the platform 3, the discharging unit 5 is accordingly moved in the X direction.

In the embodiment, the driving device 16 includes a first driving unit 161, a second driving unit 162, and a third driving unit 163. The driving units 161, 162, 163 may be motors. The first driving unit 161 and the second driving unit 162 are fixed in the base 111. The third driving unit 163 is attached to another end of the extending arm 114 away from the discharging unit 5. The positioning device 1 further includes a transmission device 18. The transmission device 18 includes a first transmission unit 181, a second transmission unit 182, and a third transmission unit 183. The transmission units 181, 182, 183 may be gear sets or fixed pulleys and lines. The first transmission unit 181 is arranged in the base 111, the second transmission unit 182 is arranged in the supporting arm 112 and fixed to the sliding block 113, and the third transmission unit 183 is arranged in the extending arm 114 and fixed to the discharging unit 5. The first transmission unit 181 is configured to transmit the drive of the first driving unit 161 to the movement of the base 111 in the X direction, transmit the drive of the second driving unit 162 to the movement of the discharging unit 5 in the Y direction, and transmit the drive of the third driving unit 163 to the movement of the discharging unit 5 in the Z direction.

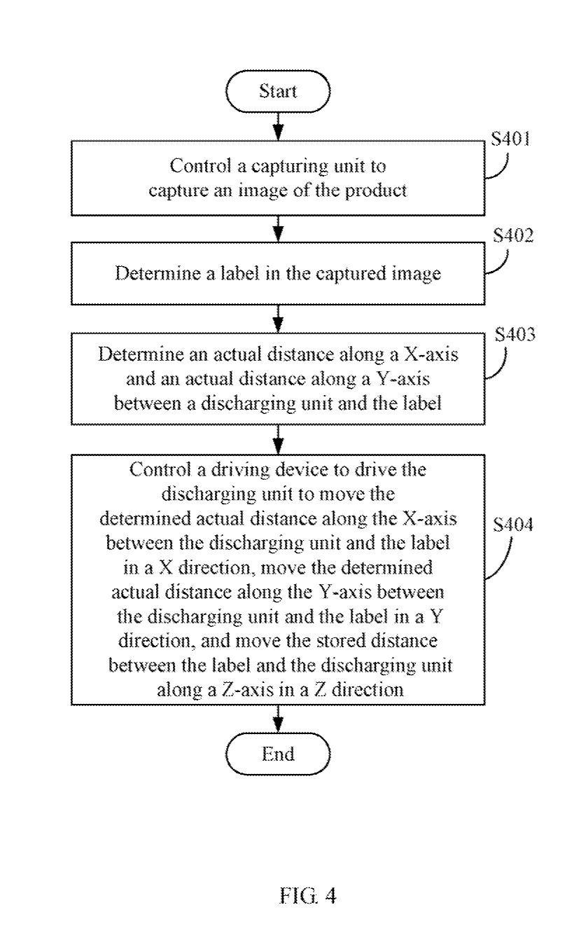

FIG. 4 shows a positioning method in accordance with an exemplary embodiment.

In step S401, the control module 171 controls the capturing unit 13 to capture an image of the product 2 in response to a user operation.

In step S402, the image analyzing module 172 determines the label 6 in the captured image. In the embodiment, the color of the label 6 is a special color which is different from the color of the product 2 and the platform 3. The image analyzing module 172 identifies the special color in the image to determine the label 6. In other embodiments, the storage unit 14 further stores a shape template of the label 6 which is different from the shape of the product 2 and the platform 3. The image analyzing module 172 determines that an object in the image whose shape is the same as the stored shape template of the label 6 is the label 6.

In step S403, the calculating module 173 determines an actual distance along a X-axis and an actual distance along a Y-axis between the discharging unit 5 and the label 6.

In detail, the center point of the captured image is considered as a center of the projected area of the capturing unit 13 in the image. A two-dimensional Cartesian coordinate system is established and the center of the captured image is set to be the origin or zero point of the Cartesian coordinate system. The calculating module 173 determines a virtual distance along the X-axis and a virtual distance along the Y-axis between the center point of the captured image and the label 6 in the captured image, and determines an actual distance along the X-axis and an actual distance along Y-axis between the capturing unit 13 and the label 6 in the real-life according to the stored ratio, and the determined virtual distance along the X-axis and the determined virtual distance along the Y-axis. The calculating module 173 further determines the determined actual distance along the X-axis between the capturing unit 13 and the label 6 is the actual X-axis difference between the discharging unit 5 and the label 6, obtains the distance between the capturing unit 13 and the discharging unit 5 along the Y-axis detected by the distance detection unit 15, and determines that the actual distance along the Y-axis between the discharging unit 5 and the label 6 is equal to the actual distance along the Y-axis between the capturing unit 13 and the label 6 subtracting the distance between the capturing unit 13 and the discharging unit 5 along the Y-axis.

In step S404, the driving module 174 controls the driving device 16 to drive the discharging unit 5 to move the determined actual distance along the X-axis between the discharging unit 5 and the label 6 in the X direction, move the determined actual distance along the Y-axis between the discharging unit 5 and the label 6 in the Y direction, and move the stored distance between the label 6 and the discharging unit 5 along the Z-axis in the Z direction.

In the embodiment, the method of controlling the discharging unit 5 to discharge is executed after the method of controlling the driving device 16 to drive the discharging unit 5 to move.

In detail, the executing module 175 controls the discharging unit 5 to discharge a preset number.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A positioning device to position a target test spot of a product which is placed on a platform and perform an electrostatic discharge (ESD) test on a target test spot via a discharging unit, the product comprising a plurality of test spots, a label being manually attached to one of the test spots to identify the target test spot, the positioning device comprising:
a supporting member, for the discharging unit to be movably arranged on the supporting member;
a capturing unit fixed to the supporting member to capture an image of the product;
a storage unit storing a ratio of image size of the object in the image captured by the capturing unit to a real-life size of the object and a distance between the discharging unit and the label along a Z-axis;
a distance detection unit configured to detect the distance between the capturing unit and the discharging unit along a Y-axis;
a driving device configured to drive the discharging unit to move; and
a processor configured to control the capturing unit to capture an image of the product in response to a user operation, determine the label in the captured image, determine a virtual distance along a X-axis and a virtual distance along the Y-axis between the capturing unit and the label in the image, to determine an actual distance along the X-axis and an actual distance along the Y-axis between the discharging unit and the label, according to the stored ratio of image size of the object in the image captured by the capturing unit to a real-life size of the object and the detected distance between the capturing unit and the discharging unit along the Y-axis, and control the driving device to drive the discharging unit to move the determined actual distance along the X-axis between the discharging unit and the label in the X direction, to move the determined actual distance along the Y-axis between the discharging unit and the label in the Y direction, and to move the stored distance between the label and the discharging unit along the Z-axis in the Z direction.

2. The positioning device as described in claim 1, wherein the processor is further configured to control the discharging unit to discharge a preset number.

3. The positioning device as described in claim 1, wherein the processor is configured to:
determine a set of coordinate of the label in the image, consider a center of the projected area of the capturing unit in the image as a center point of the captured image, determine a virtual distance along the X-axis and a virtual distance along the Y-axis between the center point of the captured image and the label in the captured image, and determine an actual distance along the X-axis and an actual distance along the Y-axis between the capturing unit and the label in the real-life according to the stored ratio of the image size of the object in the image to real-life size of the object, and the determined virtual distance along the X-axis and the determined virtual distance along the Y-axis; and
determine the determined actual distance along the X-axis between the capturing unit and the label as the actual distance along the X-axis between the discharging unit and the label, obtain the distance between the capturing unit and the discharging unit along the Y-axis detected by the distance detection unit, and determine that the actual distance along the Y-axis between the discharging unit and the label is equal to the actual distance along the Y-axis between the capturing unit and the label subtracting the detected distance between the capturing unit and the discharging unit along the Y-axis.

4. The positioning device as described in claim 1, wherein the color of the label is a special color which is different from the color of the product and the platform, the processor is configured to identify the special color in the image to determine the label.

5. The positioning device as described in claim 1, wherein the storage unit further stores a shape template of the label which is different from the shape of the product and the platform, the processor is configured to determine that an object in the image whose shape is the same as the stored shape template of the label is the label.

6. The positioning device as described in claim 1, wherein the supporting member comprises a base and a supporting arm; the supporting arm is perpendicularly secured to the base, the capturing unit is fixed to the supporting arm.

7. The positioning device as described in claim 6, wherein the supporting member further comprises a sliding block and an extending arm; the sliding block is slidably sleeved on the supporting arm; the extending arm perpendicularly extends through the sliding block and the supporting arm, and is fixed to the sliding block; and the discharging unit is movably arranged on a first end of the extending arm and is able to be moved in the Z direction.

8. The positioning device as described in claim 7, wherein the driving device comprises a first driving unit, a second driving unit, and a third driving unit, the first driving unit and the second driving unit are fixed in the base, the third driving unit is attached to a second end of the extending arm away from the discharging unit; the positioning device comprises a first transmission unit, a second transmission unit, and a third transmission unit; the first transmission unit is arranged in the base to transmit the drive of the first driving unit to the movement of the base in the X direction; the second transmission unit is arranged in the supporting arm and fixed to the sliding block, the second transmission unit is configured to transmit the drive of the second driving unit to the movement of the discharging unit in the Y direction; the third transmission unit is arranged in the extending arm and fixed to the discharging unit, the third transmission unit is configured to transmit the drive of the third driving unit to the movement of the discharging unit in the Z direction.

9. A positioning method applied on a positioning device, the positioning device being configured to position a target test spot of a product which is placed on a platform and perform an electrostatic discharge (ESD) test of on target test spot via a discharging unit, the product comprising a plurality of test spots, a label being manually attached to one of the test spots to identify the target test spot; the positioning device comprising a supporting member, a capturing unit, a storage unit, a distance detection unit, and a driving unit; the discharging unit being movably arranged on the supporting member; the capturing unit being fixed to the supporting member to capture an image of the product; the storage unit storing a ratio of image size of the object in the image captured by the capturing unit to a real-life size of the object and a distance between the discharging unit and the label along a Z-axis; the distance detection unit being configured to detect the distance between the capturing unit and the discharging unit along a Y-axis; the driving device being configured to drive the discharging unit to move; the method comprising:
controlling the capturing unit to capture an image of the product in response to a user operation;
determining the label in the captured image;
determining a virtual distance along a X-axis and a virtual distance along the Y-axis between the capturing unit and the label in the image, to determine an actual distance along the X-axis and an actual distance along the Y-axis between the discharging unit and the label, according to the stored ratio of image size of the object in the image captured by the capturing unit to a real-life size of the object and the detected distance between the capturing unit and the discharging unit along the Y-axis; and
controlling the driving device to drive the discharging unit to move the determined actual distance along the X-axis between the discharging unit and the label in the X direction, the determined actual distance along the Y-axis between the discharging unit and the label in the Y direction, and the stored distance between the label and the discharging unit along the Z-axis in the Z direction.

10. The positioning method as described in claim 9, wherein the method further comprises:
controlling the discharging unit to discharge a preset number.

11. The positioning method as described in claim 9, wherein the method further comprises:
determining a set of coordinate of the label in the image, considering a center of the projected area of the capturing unit in the image as a center point of the captured image, determining a virtual distance along the X-axis and a virtual distance along the Y-axis between the center point of the captured image and the label in the captured image, and determining an actual distance along the X-axis and an actual distance along the Y-axis between the capturing unit and the label in the real-life according to the stored ratio of the image size of the object in the image to real-life size of the object, and the determined virtual distance along the X-axis and the determined virtual distance along the Y-axis; and
determining the determined actual distance along the X-axis between the capturing unit and the label is the actual distance along the X-axis between the discharging unit and the label, obtaining the distance between the capturing unit and the discharging unit along the Y-axis detected by the distance detection unit, and determining that the actual distance along the Y-axis between the discharging unit and the label is equal to the actual distance along the Y-axis between the capturing unit and the label subtracting the detected distance between the capturing unit and the discharging unit along the Y-axis.

12. The positioning method as described in claim 9, the color of the label being a special color which is different from the color of the product and the platform, wherein the method further comprises:
identifying the special color in the image to determine the label in the image.

13. The positioning method as described in claim 9, the storage unit further storing a shape template of the label which is different from the shape of the product and the platform, wherein the method further comprises:
determining that an object in the image whose shape is the same as the label shape template is the label.
